(19) United States
(12) Patent Application Publication
(10) Pub. No.: US 2014/0057453 A1
(43) Pub. Date: Feb. 27, 2014

(54) DEPOSITION OF THIN FILMS ON ENERGY SENSITIVE SURFACES

(71) Applicants: John Madocks, Tucson, AZ (US); Walter Seaman, Tucson, AZ (US)

(72) Inventors: John Madocks, Tucson, AZ (US); Walter Seaman, Tucson, AZ (US)

(21) Appl. No.: 13/985,012

(22) PCT Filed: Feb. 10, 2012
(86) PCT No.: PCT/US12/24618

§ 371 Date: Nov. 12, 2013

Related U.S. Application Data
(60) Provisional application No. 61/441,607, filed on Feb. 10, 2011.

(51) Int. Cl. C23C 16/50

(52) U.S. Cl. CPC C23C 16/50
USPC 438/762; 427/569; 118/723 R

(57) ABSTRACT

A process for plasma deposition of a coating is provided that includes exposure of a surface of a substrate to a source of adsorbate molecules to form a protective layer on the surface. The protective layer is then exposed in-line to a plasma volume to react the protective film to form the coating. This process occurs without an intermediate evacuation to remove the adsorbate molecules prior to contact with the plasma volume. As a result, kinetic ion impact damage to the surface is limited while efficient operation of the plasma deposition system continues.

### RELATED APPLICATIONS

This application claims priority benefit of U.S. Provisional Application Ser. No. 61/441,607 filed 10 Feb. 2011; the contents of which are hereby incorporated by reference.

### FIELD OF THE INVENTION

The present invention relates in general to in-line deposition coating on energy sensitive surfaces and in particular to formation of a protective thin film to protect the surface during deposition.

### BACKGROUND OF THE INVENTION

In the plasma deposition of thin films in continuous processes, surfaces sensitive to ion, reflected neutral, or radical induced damage are often encountered. Examples of sensitive surfaces are emitter surfaces of crystalline silicon solar cells, transistor surfaces of organic semiconductors, and thin films of silver. In the plasma deposition process, substrate surfaces are subjected to a flux of ions, high energy neutrals, free radicals, and electrons. These particles often have thermal energies that exceed 10 eV and even 100 eV. The impingement of this flux is clearly unacceptable for surfaces that are often sensitive to energies above 5 eV. In response, it is common to modify process conditions are often modified to reduce the energy of the particles on the surface. These modifications often include raising the process pressure to enhance the collisional cooling of the particles and increasing the travel distance to the substrate to provide a higher probability for collisional cooling. Unfortunately, these measures are often accompanied with an undesirable degradation of the properties of the deposited thin film. The influence of incident particle energy on the film properties of a sensitive material like Ag and the energy ranges are relevant to these types of processes. In prior art FIG. 1, the defect density of a silver thin film as a function of the arriving energy of incident species is plotted in a carefully controlled experiment. This figure shows that between 20 and 40 eV a marked increase in film defect density is observed. This illustrates an important point; every surface exhibits some threshold energy for damage. Handbook of Ion Beam Processing Technology, Chapter 10, page 177. Noyes Publications, 1989. Unfortunately, it is not always possible in industrial processes to control the incident energy of the arriving atoms, but many times the range of energies exposed to the surface can be controlled. The prior art provides a trend for the thickness of material required to protect a given underlying surface from damage. For instance, the interaction of argon, helium, and neon ions with carbon has been measured by Choi et al. Choi and Kang, Low energy threshold behavior of He, Ne, Ar penetration in graphite”, Chemical Physics Letters, Vol. 173, No. 4, 1990. The masses of these ions represent the range of ion masses encountered in industrial plasma processes and carbon is a good representation of the type of adsorbate molecules of interest. As shown in prior art Table I, there is a threshold energy for the penetration of all the ions at 10 eV. Ions of 10 eV or less energy will not penetrate the first layer of the carbon. This first layer of carbon is referred to as a monolayer and is typically 3 to 5 Angstroms in thickness, depending on bonding configuration. According to nuclear collision theory, the energy of arriving ions with the surface is divided about equally between the adsorbed surface atoms and the incoming ion. Therefore, it would require about one monolayer of carbon to stop the progress of a 10 eV ion and about 2 monolayers for a 20 eV ion and so on. Table I shows the calculated number of monolayers to stop arriving ions based on this calculation for carbon. By adding enough monolayers of adsorbate, the underlying sensitive surface can be protected from impinging harmful ion energies.

TABLE I
Estimated number of carbon monolayers to stop
ions with various energies per Choi et al.

| | Number of Stopping |
|---|---|
| Energy (eV) | Monolayers |
| 10 | 1 |
| 20 | 2 |
| 30 | 2 |
| 40 | 2 |
| 50 | 3 |
| 60 | 3 |
| 70 | 3 |
| 80 | 4 |
| 90 | 4 |
| 100 | 4 |

Thus, there exists a need to reduce reactive particle induced surface damage associated with plasma deposition. There further exists a need to protect a substrate without resort to separate distinct processes prior to thin film deposition.

### SUMMARY OF THE INVENTION

A process for plasma deposition of a coating is provided that includes exposure of a surface of a substrate to a source of adsorbate molecules to form a protective layer on the surface. The protective layer is then exposed in-line to a plasma volume to react the protective film to form the coating. This process occurs without an intermediate evacuation to remove the adsorbate molecules prior to contact with the plasma volume. As a result, kinetic ion impact damage to the surface is limited while efficient operation of the plasma deposition system continues.

### BRIEF DESCRIPTION OF THE DRAWINGS

FIG. 1 is a prior art plot of defect density as a function of incident atom impact energy for silver.

FIG. 2 is a prior art plot of noble gas atom trapping in an sp² hybridized carbon substrate as a function of noble gas atom impact energy. Energy-dependent behaviors of He (◯), Ne (□), and Ar (Δ) trapping measured by time domain spectroscopy (TDS). For all data points the total ion dose is fixed at 1.1×10¹⁴ ions. The error bars are indicated for several points as estimated from repeated measurements.

FIG. 3 is a schematic depicting operation of the present invention in conjunction with a sputter cathode.

FIG. 4 is a schematic depicting operation of the present invention in conjunction with an alternating current magnetron.

FIG. 5 is a schematic of the reactive species interactions with an adsorbate protective layer according to the present invention.

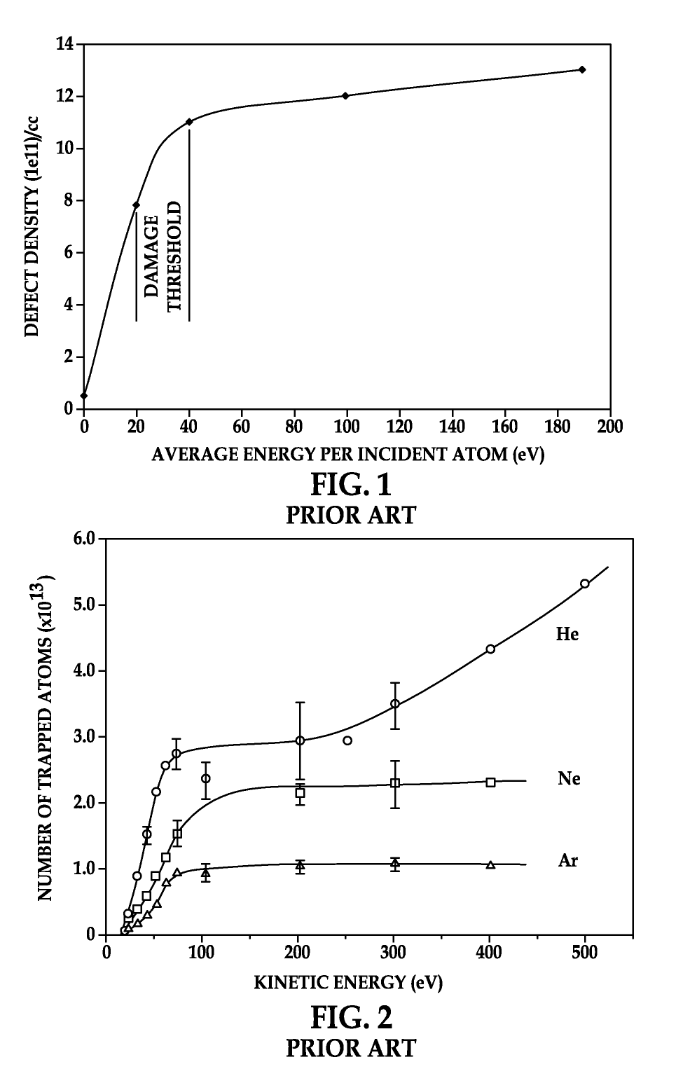

### DETAILED DESCRIPTION OF THE PREFERRED EMBODIMENTS

The present invention has utility in plasma deposition of thin films. According to the present invention, damage to sensitive surfaces is inhibited by a chemical modification to the sensitive surface before it encounters the plasma volume OF a plasma deposition process. This chemical modification utilizes surface chemistry and gas phase kinetics to deposit adsorbate molecules with a surface coverage sufficient to limit damage to the energy sensitive surface. The ability of the adsorbate to limit penetration to the underlying substrate surface is dependent on the mass of the incident species, incident species translational velocity vector, and the chemical and physical characteristics of the adsorbate.

As used herein, a “monolayer” is defined as greater than 30% areas coverage and single layer of closed packed molecules. This term is used herein relative to the terms of a “sub-monolayer” denoting equal to or less than 30% surface coverage as measured by BET; and “multiple monolayers” denoting laminar stacks of two or more monolayers.

The present invention in order to provide a degree of protection to a vulnerable substrate surface from damage in the course of being subjected to plasma deposition occurs in a continuous process through control of the characteristics of adsorbed layers on the substrate surface being subjected to plasma deposition. In contrast to atomic layer deposition (ALD) chemistries that may involve radical enhancement, the present invention is noted as being an in-line process that precludes an intermediate evacuation step to remove all but the chemisorbed monolayer from the substrate surface. Rather, the present invention in allowing a user to adjust the thickness and chemical composition of an adsorbate layer or layers, a reactive and protective thin film is formed on the substrate surface so as to inhibit reactive particle induced surface damage.

The surface coverage of an adsorbate is determined by the rate of arrival of the adsorbate molecules, adsorbate residence time on the surface, and adsorbate rate of desorption.

The rate of adsorbate molecules arriving on the surface in a vacuum per square cm per second is dependent on their partial pressure. This number is calculated by knowing the mass of the molecule and the ambient temperature according to (1).

$$J = 3.51 \times {10}^{22} * \frac{p}{\sqrt{M \cdot T}} \frac{molecules}{{cm}^{2} \cdot sec} \\ P = Particle pressure of molecule ( torr ) \\ M = Molecular Weight ( g \text{/} mole ) \\ T = Temperature ( K ) \qquad ( 1 )$$

The accepted coverage limit for a monolayer of adsorbate is about 5×10¹⁴ molecules per cm² on most surfaces. The first layer adsorbed to the surface forms a bond directly with the underlying substrate and is called the chemisorbed layer. The chemisorbed layer is composed of a molecular species that persists in an equilibrium amount on the surface in quantities to limit high energy plasma ion impact damage to the surface and underlying substrate. The present invention is contrary to the accepted wisdom of the field that advocates rigorous surface cleaning in advance of plasma deposition. The equilibrium residence time of chemisorbed layers on surfaces can range from several microseconds to several days or even more. Additional adsorbate molecules adhere to the chemisorbed monolayer, yet these physisorbed layers are bound more weakly than the chemisorbed layer and therefore have lower equilibrium residence dwell times on the surface under like conditions. For example, chemisorbed water at room temperature has a residence time of more than 25 hours and physisorbed water has a residence time of only several microseconds. Koch et al., “Real-time measurement of residence times of gas molecules on solid surfaces”; Chemical Physics Letters 275 (1997) pp. 253-260 For comparison, the chemisorbed layer of methanol exhibits a residence time of several milliseconds and only tenths of a microsecond for subsequent physisorbed layers. Zhou et al., “Low-pressure methanol oxidation over Cu (110) surface under stationary conditions: (I) reaction kinetics”; Journal of Catalysis 230 (2005) pp. 166-172. At a typical adsorbate pressure of 2 millitorr, the equivalent number of molecules for 2000 adsorbate monolayers arrives at the substrate surface every second. If a sufficient number of these arriving molecules stick to the surface, one or more monolayers are adsorbed to the surface according to the criterion described above. Every adsorbate molecule has a characteristic ability to stick to the underlying surface and to itself, and this characteristic dictates the total number of monolayers that can be formed. Such properties are readily simulated by conventional ab initio calculations and kinetic equilibrium calculations. In the present invention, the formation of the absorbed monolayers is used to our advantage to form a protective layer over the sensitive surface prior to exposure to a plasma environment. The protective layer is preferably at least a monolayer in thickness. It is appreciated that the equilibrium thickness of physisorbed layers and the stability underlying substrate-chemisorbed layer as a monolayer or sub-monolayer are readily controlled according to the present invention as operational parameters of an otherwise conventional plasma deposition system to retain desired deposition rates and energies while inhibiting plasma sputtering and other forms of substrate degradation.

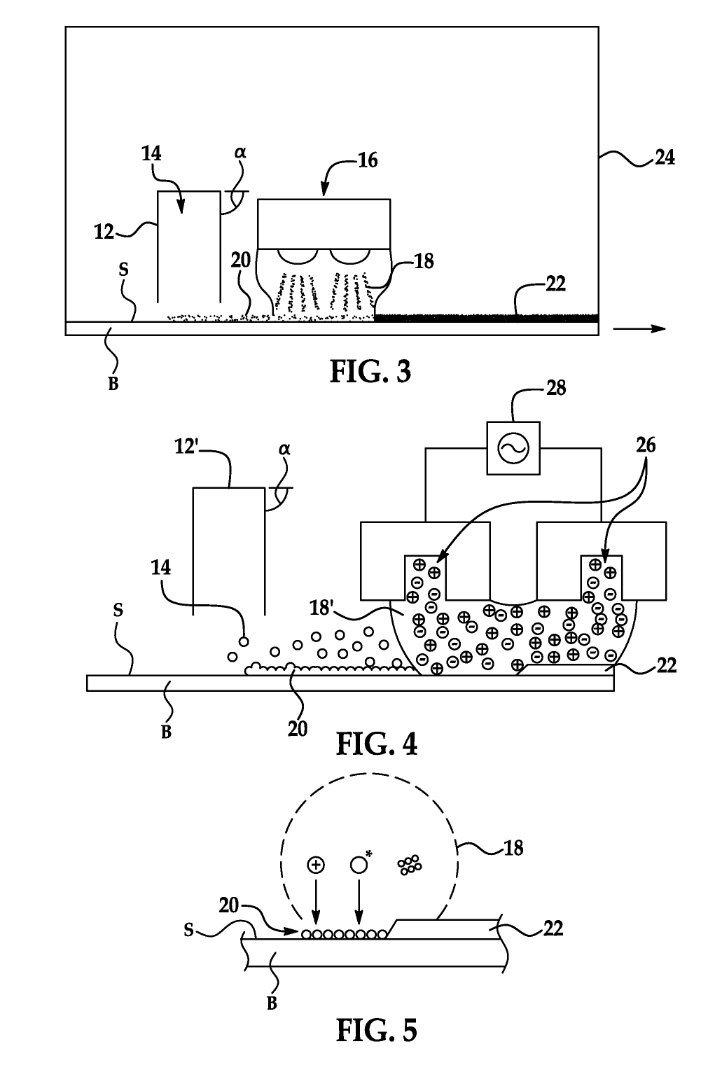

According to the present invention, an adsorbate molecule source (not shown) such as a gas cylinder or liquid vapor diffusion system conventional to the art is provided in fluid communication to the plasma generating volume from the substrate. The adsorbate source is readily positioned in a variety of positions relative to the plasma generating volume so as to adhere adsorbate molecules on the surface of the substrate such that the adsorbate molecules absorb at least a portion of the impact energy associated with incident atoms, radicals, and ions impacting the substrate surface in the plasma. By way of example, an adsorbate source is positioned upstream, within, or downstream relative to the plasma volume in fluid communication so long as a sub-monolayer, or more preferably at least a monolayer, of reactive adsorbate molecules is adhered to the surface of the substrate during plasma particle impact with the substrate surface. With reference to FIG. 3, a gas manifold 12 is used to administer a reactive adsorbate molecule 14 from the adsorbate source onto the surface S of a bulk substrate B and is optionally moved crosswise relative to a sputter cathode 16. The sputter cathode 16 creates a plasma zone 18 in the region adjacent to surface S. An adsorbate molecules form a protective layer on the surface S during plasma deposition in plasma volume 18 is denoted at 20 while the deposition coating into which protective layer 20 is converted is shown graphically at 22. The plasma deposition chamber housing is shown at 24 to illustrate the in-line attributes of the present invention and the lack of intermediate evacuation between adsorption and deposition. Additionally, while manifold 12 and adsorbate molecule flow 14 are denoted as being generally orthogonal to surface S, it is appreciated that based on the nature of gas phase kinetics, operating versions of a gas manifold 12 are readily provided that extend through an angle denoted as a inclusive of gas delivery parallel to substrate S. Additionally, in instances when a plasma generator operates in a pulsatile fashion, it is appreciated that adsorbate molecules can be adsorbed onto a substrate S in a kinetically counterpulsatile mode relative to generation of a plasma volume. In such an instance, a manifold 12 is optionally positioned internal to a sputtering cathode 16 or even downstream therefrom so long as adsorbate molecules 14 are readily contact the surface S prior to, or during, plasma generation in the plasma volume 18 so as to participate in the formation of coating 22. In instances when a manifold 12 is located downstream as denoted by the arrow symbolizing movement of substrate B in that direction, it is preferred that the flow of adsorbate molecules be generally parallel (α=0) to assure prior adsorption of adsorbate molecules. Exemplary adsorbate molecules 14 that adhere to surface S to form a protective layer 20 subsequently react with the plasma in plasma volume 18 so as to be incorporated into the resultant coating 22 illustratively include water; ammonia; hydrogen peroxide; silanes that are gaseous at standard temperature and pressure (760 torr, 25° C.); organics such as alcohols, ethers, lactones, lactams, ketones, esters, carboxylic acids, and oxiranes that are gaseous or liquids at that are gaseous at standard temperature and pressure, and deuterated versions thereof. It is of note that the deuterated analogs of water and ammonia while reactively similar have larger impact cross sections and have appreciably different adsorption kinetics. It is appreciated that silanes and organics operative herein can be linear, branched, or cyclic molecules. Additionally, adsorbate molecules 14 are appreciated to be conventional chemical vapor deposition (CVD) organometallic precursors. Such CVD precursors for plasma-enhanced CVD are conventional to the art and used to form protective layer 20 consistent with equation (1).

As the substrate moves into the plasma volume 18, the number of collisions with the adsorbate molecules in the protective layer 20 and other gas phase species increases. The absorption of the molecules 14 on the surface S to form protective layer 20 is dependent on their partial pressure and chemistry. As the adsorbed sub-monolayer, monolayer, or monolayers form a protective layer 20, the layer 20 absorbs the energy of incident ions, radicals, and neutrals from the plasma in the plasma volume 18. The adsorbate reactivity is optionally activated by the weak afterglow of the plasma volume 18, creating a molecular species that is more readily chemisorbed or physisorbed.

Once in the plasma volume 18, the protective layer 20 is converted into a desired coating 22 due to the flux of ions and radicals from the plasma. This chemical activation is an important feature of the invention as the protective layer 20 must be converted to a desirable coating 22. The penetration energy threshold of the adsorbate is dependent on the unique physical and chemical properties of the molecules 14 and is readily optimized for particular deposition conditions. The process conditions responsible for the formation of the adsorbate layer are readily tuned to adjust the following process features:
1) increase the flux of adsorbate 14 to the surface S,
2) change the identity of adsorbate 14 to improve binding potential or increase the number of physisorbed monolayers,
3) reduce the energy of incident ions, radicals, or neutrals in the plasma volume.

A schematic of plasma-enhanced CVD deposition is provided in FIG. 4 where like numerals have the meaning ascribed thereto with respect to FIG. 3. In FIG. 4, a gas inlet 12′ is provided relative to manifold 12 and illustrates a manifold more specific to delivery of high molecular weight adsorbate molecules 14. A plasma volume 18′ is shown as generated by a dual plasma generator 26 operating with an alternating power source 28.

FIG. 4 shows the important aspects of the surface chemistry in the chemical activation process. The incident ions, radicals, or neutrals from the plasma must be of sufficient energy to drive the reaction chemistry of the adsorbate molecule to react with the plasma constituents to yield the desired thin film.

FIG. 5 is a schematic cartoon of the reactive species interaction with an adsorbate protective layer according to the present invention, magnified relative to FIGS. 3 and 4. In FIG. 5 like reference numerals have the meaning ascribed thereto with respect to FIGS. 3 and 4 with protective layer 20 now being denoted as spheres symbolic of individual chemisorbed molecules on the surface S. Symbolic ions and radicals are denoted with an incident impact energy impinging on the protective layer 20 with the impact energy that previously damaged surface S being partly absorbed by the adsorbed species taking up the layer 20. Instead of this adsorbed impact energy merely creating collisional displacement of adsorbate species from the sensitive surface S, this energy is used to induce reaction between the adsorbate species and impacting ions and/or radicals in the plasma volume to create the coating 22 and in the process create molecular fragments which are removed.

This invention is applicable to a number of important industrial thin film processes. By way of example, the manufacture of silver reflective coatings by sputtering a protecting dielectric coating is used to prevent oxidation and sulfurization of the silver. The deposition of a dielectric coating directly on the silver reduces manufacturing complexity and the use of a plasma enhanced CVD (PECVD) technology increases the throughput due to the relatively high rates of deposition offered by the PECVD process. This invention is operative to form highly reflective Ag/SiO₂ dielectric stacks with less damage to the plasma sensitive underlying Ag substrate surface.

The deposition of thin films emitters of crystalline silicon photovoltaic solar cells improves their absolute efficiency by up to 2%. The emitter surface is sensitive to plasma damage that causes surface defects responsible for recombination of hole and electron charge carriers. The recombination of electrons and holes is quantified by the minority carrier lifetime. The present invention has been utilized to improve the carrier lifetime from tens of microseconds to thousands of microseconds on n-type emitter surfaces by deposition of SiN:H from an adsorbate chemistry of SiH₄ (silane), NH₃ (ammonia), or a combination thereof with deficient reagent being supplied via the plasma volume. Deposition of Al₂O₃ onto p-type semiconductor surfaces is an emerging mechanism to improve solar cell efficiency by increasing the minority carrier lifetime. The present invention has demonstrated the capability to improve the p-type minority carrier lifetime from tens of microseconds to greater than a thousand microseconds by a plasma deposition of Al₂O₃ from TMA (trimethyl aluminum) adsorbate on p-type emitter surfaces.

Patent documents and publications mentioned in the specification are indicative of the levels of those skilled in the art to which the invention pertains. These documents and publications are incorporated herein by reference to the same extent as if each individual document or publication was specifically and individually incorporated herein by reference.

The foregoing description is illustrative of particular embodiments of the invention, but is not meant to be a limitation upon the practice thereof. The following claims, including all equivalents thereof, are intended to define the scope of the invention.

1. A process for plasma deposition of coating comprising:
exposing a surface of a substrate to a source of adsorbate molecules to form a protective layer on the surface; and
exposing the protective layer in-line to a plasma volume to react the protective layer to form the coating.

2. The process of claim 1 wherein the adsorbate molecules form at least one monolayer on the surface.

3. The process of claim 1 wherein the adsorbate molecules form from two to ten monolayers.

4. The process of claim 1 wherein the adsorbate molecules are at least one of water, ammonia, hydrogen peroxide, silanes alcohols, ethers, lactones, lactams, ketones, esters, carboxylic acids, and oxiranes, and deuterated versions thereof.

5. The process of claim 1 wherein the adsorbate molecules are organometallic chemical vapor deposition precursor molecules.

6. The process of claim 1 wherein the coating is a dielectric.

7. The process of claim 1 wherein the coating is a silicon oxide and the substrate is silver.

8. The process of claim 1 wherein the coating is a SiN:H and the substrate is an n-type emitter.

9. The process of claim 1 wherein the coating is a Al₂O₃ derived from the absorbate molecules of trimethyl aluminum and the substrate is an p-type semiconductor.

10. The process of claim 1 wherein the monolayer of the protective layer in contact with the surface is a chemisorbed monolayer and a subsequent monolayer being physisorbed.

11. A plasma deposition system for performing the process of claim 1 comprising:
a plasma source chamber housing;
a plasma source located with the housing;
a gas manifold in fluid communication with an adsorbate molecule source, the gas manifold located in the housing an in-line with the plasma source to delivery adsorbate molecules onto a surface of a bulk substrate to form a protective layer on the surface prior to plasma deposition on the surface; and
a plasma power source in electrical communication with the plasma source.

12. The process of claim 2 wherein the adsorbate molecules form from two to ten monolayers.

13. The process of claim 4 wherein the coating is a dielectric.

14. The process of claim 5 wherein the coating is a dielectric.

15. The process of claim 2 wherein the coating is a SiN:H and the substrate is an n-type emitter.

16. The process of claim 2 wherein the coating is a Al₂O₃ derived from the absorbate molecules of trimethyl aluminum and the substrate is an p-type semiconductor.

17. The process of claim 2 wherein the monolayer of the protective layer in contact with the surface is a chemisorbed monolayer and a subsequent monolayer being physisorbed.

18. The process of claim 4 wherein the coating is a SiN:H and the substrate is an n-type emitter.

19. The process of claim 4 wherein the coating is a Al₂O₃ derived from the absorbate molecules of trimethyl aluminum and the substrate is an p-type semiconductor.

20. The process of claim 4 wherein the monolayer of the protective layer in contact with the surface is a chemisorbed monolayer and a subsequent monolayer being physisorbed.
